(19) United States
(12) Patent Application Publication
(10) Pub. No.: US 2008/0195561 A1
(43) Pub. Date: Aug. 14, 2008

(54) SYSTEMS AND METHODS FOR PROVIDING RENEWABLE POWER SYSTEMS BY AGGREGATE COST AND USAGE

(76) Inventor: Michael Herzig, Cold Spring, NY (US)

Correspondence Address: MEREDITH & KEYHANI, PLLC, 330 MADISON AVE., 6TH FLOOR, NEW YORK, NY, 10017, US

(21) Appl. No.: 11/673,649

(22) Filed: Feb. 12, 2007

(51) Int. Cl. G06F 17/00; G01R 21/133

(52) U.S. Cl. 705/412

(57) ABSTRACT

Systems and methods of providing power as it is generated at a consumer's premises, the method comprising: providing at least one locally based renewable power system to a consumer; storing the power system's characteristics in a database; determining the consumer's customer variables; monitoring the consumer's customer usage to provide an actual customer usage; determining power system's available incentives; determining the aggregate cost of the power system; determining the break even point of the power system according to a discount rate, amortization period and aggregate cost of the power system; determining the consumers monthly payment according to the consumer's customer variables, the actual customer usage, break even point and the aggregate cost; and billing the consumer the consumers monthly payment.

The present invention relates to systems and methods for providing locally based renewable power systems that are billed according to the aggregate cost and usage.

Many different types of panel and/or systems provide the ability to generate energy from solar power; however, many consumers find the initial payout to be prohibitive. This is because the up-front cost of solar panels/systems is higher in terms of fixed components than other sources of energy. For example, photovoltaic panels (which generate electricity directly from sunlight) are very expensive since they usually require microchip grade silicon. Therefore, the cost of panels for an average house may run from $15,000 to $35,000 (or more), not including what are often substantial installation feels. Solar Hot Water systems tend to be somewhat less expensive, but still run from $5,000 to $10,000 not including installation. These costs must then be compared to competing system. The competing system for photovoltaic panels is connecting to the local grid. This is usually included in the base price of the house, and therefore is considered to be negligible for most consumers. Solar Hot Water heaters compete with gas/oil/electric heater and heat pumps. These are all lower priced than the Solar Hot Water systems by a factor of two or three, which is critical since they are generally installed by a developer who does not benefit from the ongoing cost savings of solar power. Also, replacement usually occurs when a system breaks, and therefore the goal is a quick replacement instead of a long term investment.

Because of these cost considerations, solar panels/systems are not as widely used by consumers as they might otherwise be since they have the following benefits: they do not rely on fossil fuels which create greenhouse gases as well as other pollution; they get their energy from the sun which is a renewable resource that is freely available to all; they reduce the additional usage of fossil fuels required to transport fuels to the premises to create heat (in the case of Solar Hot Water systems); they create energy at the point of usage, creating efficiencies in transmissions; they are generally durable systems which pay for themselves over time and then can be used after they have been amortized; they decrease the demand for fuels from volatile areas of the globe; and they decrease the need for destroying natural habitats required to extract fuels.

Over the past decade, rising greenhouse gases have been directly related to an increase in global warming. This is now established scientific fact which could have grave concerns if it continues to rise unabated. This further underlines the benefit of solar panels/systems which reduce the need to generate power with fossil fuels that contribute to this issue. The realization of the Federal, State and some Local governments that fossil fuels create both environmental as well as geopolitical issues has led to a broad set of incentives at all levels. These change on a regular basis, but one example is a current federal energy bill that provides a tax credit worth up to 30 percent of the cost of residential solar panels. The credit is capped at $2,000 but can be combined with other incentives. With or without government support, consumers have had the ability to purchase solar power systems for years. The traditional method of purchasing a system and then seeking the Federal, State and Local credits suffers from drawbacks and limitations. The expense is often prohibitively large, with up front costs that are beyond the means of many consumers, even if they were able to recoup the costs over time. If consumers had the option to purchase energy generated from solar panels/systems on their premises as it was generated rather than as an up front fixed cost, this would not only benefit the consumer in terms of long term energy pricing, but would also provide the environmental and national benefits as described above.

The primary types of systems are electric (photovoltaic) and thermal (generally for hot water). The technology for thermal systems matured relatively quickly, and these produced (and continue to produce) the highest energy content for surface area covered by the panels. The issue with them being more widely adopted has to do with price competition with inexpensive hot water heaters and the economics of how water heaters are purchased (as noted above). The technology for photovoltaic systems continues to advance with several breakthroughs likely in the next few years as start-up companies seek to mass produce panels that do not require expensive silicon. If successful, this could revolutionize the industry. Even if these technologies take longer to develop than expected, there are several other developments which enable the creation of more efficient panels while using much less silicon. Finally, annually increasing demand is leading to the creation of additional manufacturing which will likely reduce prices in the long term.

Many more Consumers would likely use locally based renewable power systems if it did not require such a relatively large upfront investment. Also, even more consumers may utilize locally based renewable power systems if they were able to pay for such systems based upon usage, similar to the process that most people use.

### SUMMARY OF THE INVENTION

The present invention relates generally to systems and methods for providing locally based renewable power systems that are billed according to the aggregate cost and usage.

According to one embodiment, a method of providing power as it is generated at a consumer's premises is provided, the method comprising: providing at least one locally based renewable power system to a consumer; storing the at least one locally based renewable power system's characteristics in a database; determining the consumer's customer variables; determining the at least one locally based renewable power system's available incentives; determining the aggregate cost of the at least one locally based renewable power system; determining the break even point of the at least one locally based renewable power system according to a discount rate and fees, amortization period of the at least one locally based renewable power system and the aggregate cost of the at least one locally based renewable power system; determining the consumers monthly payment according to the consumer's customer variables including usage; and billing the consumer for the consumers monthly payment.

According to another embodiment, a method of providing power as it is generated at a consumer's premises is disclosed, the method comprising: providing at least one locally based renewable power system to a consumer; storing the at least one locally based renewable power system's characteristics in a database; determining the consumer's customer variables including actual customer usage; monitoring the consumer's customer usage to provide an actual customer usage; determining the at least one locally based renewable power system's available incentives; monitoring said consumer's customer usage to provide an actual customer usage; determining the consumers monthly payment according to the consumer's actual customer usage and available incentives; and billing the consumer the consumers monthly payment.

A system for providing power at a consumer's premises and billing the consumer according to usage, the system comprising: at least one locally based renewable power system at a consumer's location, wherein the at least one locally based renewable power system has power system characteristics and may have available incentives and the locally based renewable power system characteristics and the potentially available incentives are stored in a database; a set of customer variables, wherein the customer variables are maintained in a database; software in communication with the database, wherein the software determines the aggregate cost of the at least one locally based renewable power system, a break even point of the at least one locally based renewable power system according to a discount rate, amortization period of the at least one locally based renewable power system and the aggregate cost of the at least one locally based renewable power system and the database determines the consumer's anticipated monthly payment according to the consumer's customer variables, the break even point and the aggregate cost, and the system determines the consumer's actual monthly payment according to the consumer's customer variables and actual usage, and provides billing to the consumer according to the consumers monthly payment.

According to another embodiment, a system for providing power at a consumer's premises and billing the consumer according to usage is provided, the system comprising: at least one locally based renewable power system at a consumer's location, wherein the at least one locally based renewable power system has power system characteristics and available incentives and the locally based renewable power system characteristics and the available incentives are stored in a database; a set of customer variables, wherein the customer variables are maintained in a database; a central processing unit in communication with the database, wherein the central processing unit determines a break even point of the at least one locally based renewable power system according to a discount rate and amortization period of the at least one locally based renewable power system and the database determines the consumers monthly payment according to the consumer's customer variables and the break even point and provides billing to the consumer according to the consumers monthly payment.

These and other features, aspects and advantages of the present invention will become better understood with reference to the following description and claims.

### BRIEF DESCRIPTION OF THE DRAWINGS

FIG. 1 depicts the present invention;

FIG. 2 depicts the present invention;

FIG. 3 depicts the present invention;

FIG. 4 depicts the present invention; and

FIG. 5 depicts the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

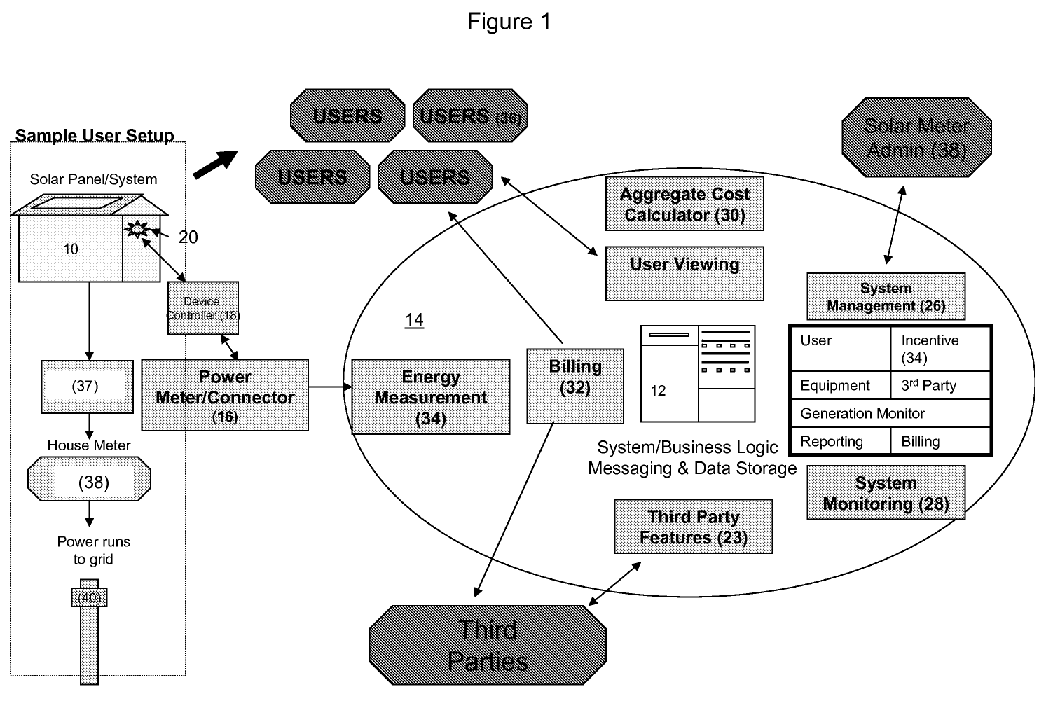

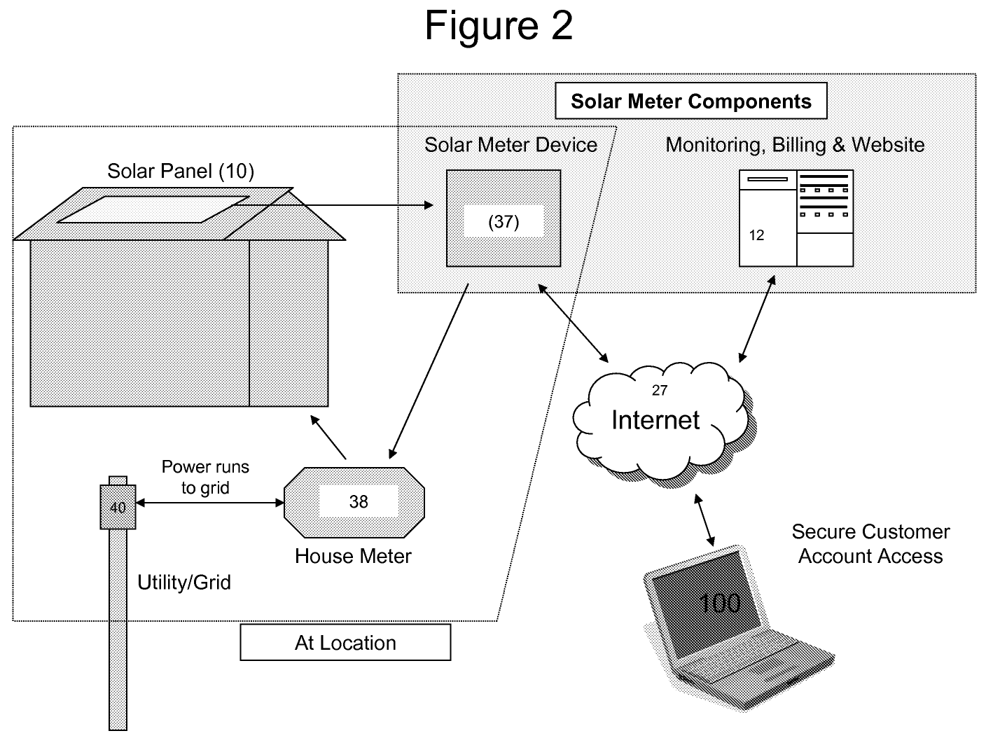

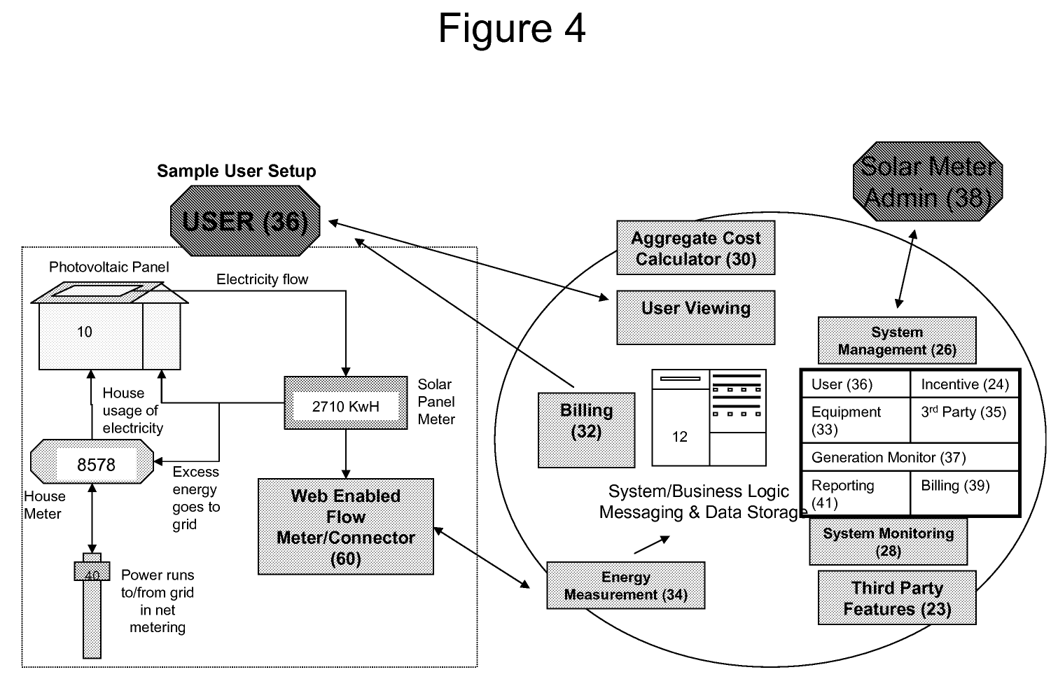

With reference to FIGS. 1-4, the present invention provides systems and methods for providing power at a consumer's premises and billing according to usage. The system comprising: at least one locally based renewable power system (10) at a consumer's location (12), wherein the at least one locally based renewable power system (10) has power system characteristics (e.g. equipment information (33)) and available incentives and the locally based renewable power system characteristics and available incentives are stored in a database (12); a set of customer variables maintained in a database (12); a central processing unit (14) in communication with the database (12), wherein the central processing unit (14) determines the aggregate cost of the at least one locally based renewable power system (10), a break even point of the at least one locally based renewable power system according to a discount rate and amortization period of the at least one locally based renewable power system (10) and the aggregate cost of the at least one locally based renewable power system (10). It should be understood that there may be available incentives according to the locally based renewable power system, or the incentives may be equal to zero when there are no available incentives for the locally based renewable power system. The central processing unit (14) determines the consumers monthly payment according to the consumer's customer variables, the break even point and the aggregate cost and provides billing to the consumer according to the consumers monthly payment. There may also be a communication means (16) in communication with the locally based renewable power system (10), the database (12) and the central processing unit (14). It should be understood, the database (12) may be in the central processing unit (14) or external and in communication without departing from the present invention. There may also be a power system device controller (18) in communication with the communication means (16). In this manner, the communication means (16) may direct a set of instructions from the database (12) and/or central processing unit (14) (such as temperatures in certain zones at certain times of the day or automatically shutting off lights (20) at certain times) to the power system device controller (18), which in turn adjusts power system devices (such as lights (20) and heating and cooling systems). The locally based renewable power system (10) may be owned by a third party owner (22) who may in turn lease it to the consumer. There may also be third party features (23), incentives (24), a system management module (26), a system monitoring module (28), an aggregate cost calculator (30), a billing module (32), an energy measurement module (34), users (36), solar meter (37) solar meter administrator (38), a house meter (38) and grid (40). Software/business logic which calculates periodic bills (e.g. monthly) for the electricity generated that can be sent to the consumer. This process will take into account: different energy rates based on consumption and renewable status, net metering, etc. The monitoring, billing and website (12) system may generate bills and reports (41) for consumers for their power used based on input cost thresholds and selected periods; determine aggregate billing for Third Parties (35); ability to create the billing (39) statements for the consumers (36); record the amount billed per period (information linked to a credit card merchant account); send email invoices to customers on their computer (100).

There may also be third party features (23), for example there may be software/business logic which allows a third party (35) to use the system to provide a white labeled service to their consumers (e.g. a local solar panel installer can offer this service through their site, and it will appear to the consumer to be that installer's brand with the bill coming from that company). Specific features of this functionality are as follows: create a branded view which represents the Third Party's company; ability to create branded billing from the Third Parties; ability to allow the Third Party to adjust their information online; ability to have the Third Party site hosted at a separate URL; a home page for the Third Party users to see their consumers and the amount of energy generated may be on the internet (27); ability to view energy generated for the Third Party's consumers according to a variety of preset periods (e.g. today, month to date, year to date, etc); ability to view past and current billing for the Third Party's consumers (e.g. past months statements, year to date billing, net metering amounts, etc.).

The present invention provides a method of providing power as it is generated at a consumer's premises, the method comprising the steps of: providing at least one locally based renewable power system (10) to a consumer. The term locally based renewable power system (10) is intended to include renewable energy systems including solar systems, solar panel systems, systems powered by solar panel systems and other locally based renewable power system, photovoltaic, thermal, wind powered to even local hydropower in some cases. Additionally, for those interested in heating and cooling their dwelling via renewable energy, geothermal heat pump systems that tap the constant temperature of the earth, which is around 7 to 15 degrees Celsius a few feet underground, are an option and save money over conventional natural gas and petroleum-fueled heat approaches. The term locally based renewable power system does not include conventional natural gas and petroleum fueled heat. The method may include the step of storing characteristic about each locally based renewable power system in a database (12). The system's characteristics may include initial power system cost, component cost, installation costs, total wattage, average sunny days per year, average prime sunlight hours per day, monthly generation estimates, current usage of electricity, percentage used during percentage generation for net metering, current utility costs during peak hours, current utility cost during off peak hours, client payment for system. All of the characteristics are relevant to the cost of operating the system. The next step may be determining the consumer's customer variables. The consumer's customer variables may include local weather, current energy usage, desirable temperature, temperature zones and local utility policies on net metering. Each of these variables is relevant to customer usage and may be stored in the central processing unit (14). The next step may be determining the locally based renewable power system's available incentives (24). By way of example, there may be state and local incentives for the solar panels (or any locally based renewable power system), a federal incentive on the equipment. There may also be incentives offered by manufactures or other third parties (22) for the equipment (e.g. (10)).

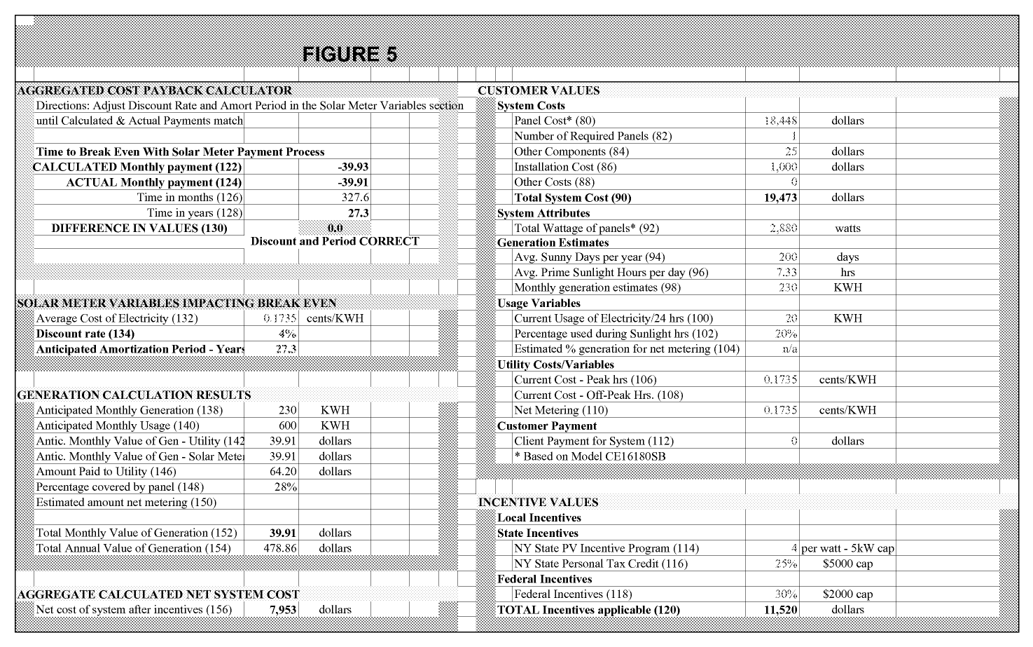

The next step is determining the aggregate cost of the at least one locally based renewable power system (10). As shown in FIG. 5, the aggregate cost of the locally based renewable power system (10) may be determined by determining the system cost (90). According to the example shown, the system cost (90) consists of the panel cost (80), the number of panels required (82), the cost of any other components (84), installation costs (86), other costs (88). As shown, the total cost in the example is 19,473 dollars and the total wattage of the panels (92) is 2,880 watts. The consumer's customer variables may include the average sunny days per year (94), the average prime sunlight hours per day (96), monthly generation estimates (98), the current usage of electricity (100), percentage used during sunlight or peak hours (102). From the information provided, the method comprises the step of determining the break even point of at the locally based renewable power system according to a discount rate and amortization period of the power system. According to the example shown the break even point may be calculated according to the following formula:

pv*(1+rate)^{nper}+pmt(1+rate*type)*((1+rate)^{nper}−1)/rate)+fv=0

Where Rate is the interest rate for the loan, Nper is the total number of payments for the loan, Pv is the present value, or the total amount that a series of future payments is worth now; also known as the principal. Fv is the future value, or a cash balance you want to attain after the last payment is made. If fv is omitted, it is assumed to be 0 (zero), that is, the future value of a loan is 0. Type is the number 0 (zero) or 1 and indicates when payments are due. O (or omitted) indicates payments are due at the end of the period. 1 indicates payments are due at the beginning of the period. This function calculates the monthly payment required to service a loan at a set Rate, for a term that is represented by a Number of Payments for a Present Value. As long as the user has 3 of the 4 main variables (PV, RATE, PMT and NPER), the user can use this equation to figure out the fourth variable. Accordingly, this may be utilized to determine the monthly payment. In the example shown, the calculated monthly moth (122) is $39.93 assuming a discount rate (134) of 4%, an amortization period of 27.3 years and an aggregate cost (156) of $7,953.00.

One purpose of the method is to determine the Breakeven Period (may be in years) for a system which is leased back to a company based on a wide variety of variables; essentially the Model takes a holistic approach to the installation of the locally based renewable power system (10), looking at the areas of a) Customer Variables b) System Variables c) Incentive Variables (local, state and federal) and d) administrator variables. Administrator variables may be fees, applied discount rate, fees and amortization period. To provide more detail on each area, the Customer Variables contain information on local weather, current energy usage, the local utilities policies on net metering, and so forth. The System Variables include the type of system being purchased, its cost, ancillary installation costs, anticipated power generation, etc. The Incentive Variables are one of the most complex parts of the calculation since they vary widely by area, and cannot always be used in conjunctions or over certain thresholds. The incentives may also be equal to zero where there are no available incentives. The Cost Model allows entry of the various elements, along with the ability to select the best option to determine the Aggregate Cost of the system to the Customer. Finally, locally based renewable power system variables are added which include a selected discount rate, amortization period as well as any fees or other financing that the Company seeks to add. These will incorporate all Third Party variables as well.

Once all of the variables have been input, the user of the Cost Model can tweak the discount rate, amortization period and any applicable fees to determine the Breakeven Point of the solar panels/system. The Cost Model works for both Photovoltaic as well as Thermal systems—save there is no net metering and incentives will likely be different. Also, instead of monitored generation of electricity, hot water usage will be measured.

The Breakeven Point is important since it enables the third party financer's and consumer's to know how much can be charged for the power generated to be profitable based on the parameters, or at least what the specific economics of the system are.

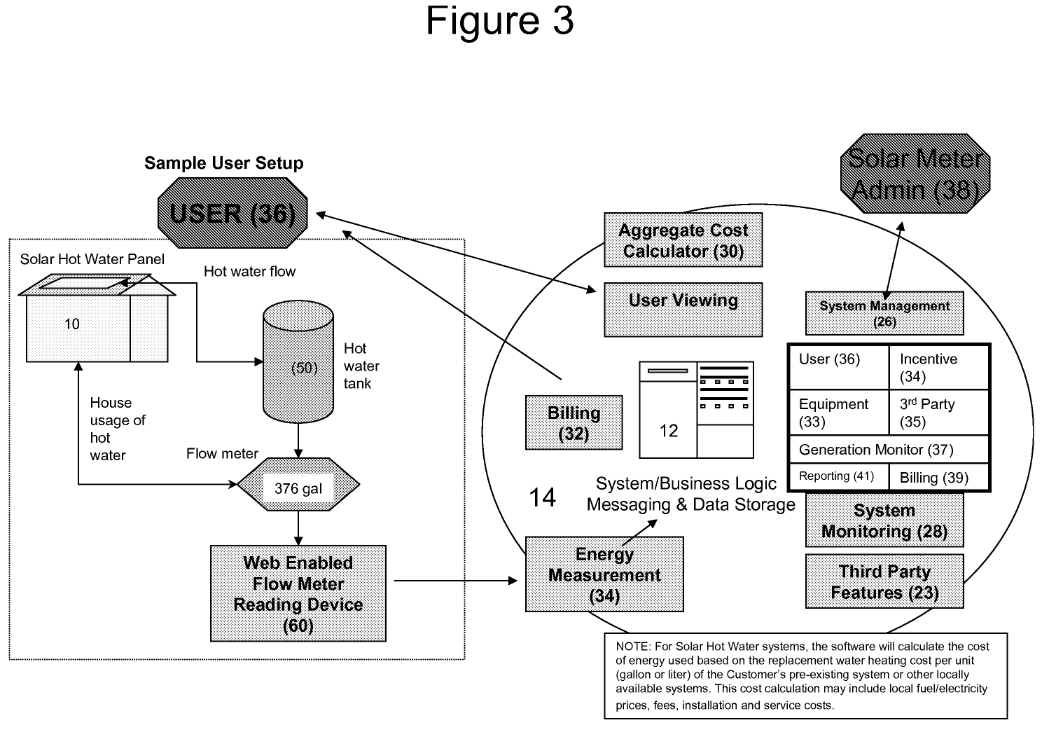

The method may further comprise the steps of monitoring the consumer's customer variables, such as usage, to provide an actual customer variable; and adjusting the consumer's monthly payment according to the actual customer variable. In this manner, the customer may be billed according to their actual usage. This represents a significant departure from the manner in which locally based renewable power systems provide energy and the related billing in that the consumer is utilizing alternate energy sources without having to outlay a large/unfeasible initial investment (in the example in FIG. 3 the consumer would have to pay $19,473), wait for state and federal incentives at tax time (approximately $7000) and then utilize the system to provide power. In the current system, the consumer would pay the actual average monthly payment (124) of $39.91 for the power generated. There may be a range of costs for the power, since this may rise or fall over time based on state and utility policies. Also, there may be a range for the price to cover both the provider's and consumer's risks. It may be desirable to start with estimated billing according to a discount rate and fees, aggregate cost, and amortization period of the locally based renewable power system. After a certain period (for example, one month) the monthly payment may be according to actual usage, wherein the cost is determined to ensure the cost of the locally based renewable power system would be paid off taking into account the actual usage, the discount rate and fees and amortization period of the system. In this manner, a locally based renewable power system can be billed, for the first time, according to usage instead of as an initial large expense.

The method may also comprise the step of monitoring the system from a remote location. The method may comprise the step of generating an alert when the customer variables are a prescribed percentage different than historical averages. For example, if the average sunny days per years are 100 and fifty (50) days go by without it being sunny, an alert may be generated which may be emailed, messaged or mailed to the consumer as well as the third party owner of the equipment. For many reasons it is desirable to monitor and store the consumer's customer variables, the break even point and the aggregate cost. This allows the consumer to be charge based on actual usage. If the homeowner with a system sells the house, the past usage is a useful predictor of future usage. If a new third party financer decides to buy out the lease, they will be able to calculate their rate of return.

According to another aspect of the present invention, the method may comprise the step of remotely changing at least one of the consumer's customer variables according to the consumer's desired consumer monthly payment. For example, the consumer may state, I would like to pay $150 per month. This may present itself as a request for proposals to a financer. The temperature and temperatures according to zone may even be remotely controlled according to the amount the consumer wants to pay. There may be a third party owner, wherein the third party owner owns the at least one locally based renewable power system and leases the system to the consumer. The third party owner/financer may decide they are willing to lease the equipment, based on the consumers usage for that amount. For example, a company may have a surplus of solar panels that they cannot sell and there may be a consumer who is willing to pay $150 per month. While this may not be as much as the company would hope to get, it is better than having the surplus solar panels never sell and become obsolete. The third party owner may also lease the locally based renewable power system to a third party financer. The third party financer is then responsible for billing the consumer according to their usage or their monthly agreement based on forecasts.

It is also envisioned that the consumer may sell energy back to a recipient, income may be received from the recipient and the aggregate cost adjusted as well as the consumer's monthly payment. The income may be received by the third party owner, consumer or third party financer according to the ownership of the system.

The locally based renewable power system may be a solar hot water heater, as shown in FIG. 3. In this case, a water meter is attached to the solar hot water tank (50) to determine how much hot water a house actually uses from the system. Then, an enabled device (with software developed to bring the Invention to market), will read the water meter on an ongoing basis to determine actual usage. The cost that the consumer will be charged for this usage is based on the following variables: Ag=Aggregate Cost of hot water per unit (e.g. Gallon), U=Actual Usage, MX=Maximum Monthly Charge. The equation for calculating the monthly bill may be as follows:

Amount Billed=MX or Ag×U (whichever is lower)

Calculating the Aggregate Cost for a Solar Hot Water system involves additional steps. This utilizes the applicable Customer, System, Incentive and Administrative values in the cost model. However, instead of using net metering as a System variable, a Solar Hot Water system will require the following variables to be used:
ER=Units of Energy Required by the water heater to create one Unit of Hot Water
C=Cost of energy
F=Fees
D=Discounts
HW=Units of Hot Water used during the billing cycle
   Therefore, the Aggregate Cost per unit is calculated as follows:

Ag=((ER×C)+(F−D))/HW

The formula is illustrated in this example: An average family of four uses 70 gal per day at a cost of $480 per year. This is based on 72 degree incoming water heated to 140 degrees with an electric rate of $0.09 per kilowatt hour for a high efficiency electric heater. ER can be calculated as follows:

Total gallons=25,550

ER×C=480/25,550

ER×0.09=0.01878

ER=0.2087

Therefore, using the comparable costs of the electric heater in this example, Aggregate Cost per unit, assuming no Fees or Discounts would be $0.01878 per gallon. In practice, this would normally be adjusted based on any selected incentives and fees, and then billed to the customer based on their actual usage. Also, the Maximum Monthly fee would be used to cap costs over a certain point and allow additional savings from the renewable source. The step of remotely changing at least one of the consumer's customer variables according to the consumer's desired consumer monthly payment could also be provided. For example, if the consumer stated they would pay no more than $0.02 per gallon, no changes would be required. If they stated they would not pay more than $0.017 per gallon, the temperature the water is heated to could be lowered during hours the user is at work or during the evening. In this manner, the consumer would save money and less strain would be placed on the equipment.

It should be understood that the foregoing relates to preferred embodiments of the invention and that modifications may be made without departing from the spirit and scope of the invention as set forth in the following claims.

I claim:

1. A method of providing power as it is generated at a consumer's premises, said method comprising:
providing at least one locally based renewable power system to a consumer;
storing said at least one locally based renewable power system's characteristics in a database;
determining said consumer's customer variables;
determining the aggregate cost of said at least one locally based renewable power system;
determining the break even point of said at least one locally based renewable power system according to a discount rate and fees, amortization period of said at least one locally based renewable power system and said aggregate cost of said at least one locally based renewable power system;
determining the consumers monthly payment on an ongoing basis according to said consumer's customer variables, said break even point and said aggregate cost; and
billing said consumer said consumers monthly payment.

2. A method as in claim 1, further comprising the step of:
monitoring said consumer's customer variables to provide an actual customer variable; and
adjusting said consumers monthly payment according to said actual customer variable.

3. A method as in claim 1, further comprising the step of:
determining said at least one locally based renewable power system's available incentives;
adjusting said consumers monthly payment according to said actual customer variable.

4. A method as in claim 1, wherein said at least one locally based renewable power system's characteristics are selected from the group consisting of initial power system cost, component cost, installation costs, total wattage, average sunny days per year, average prime sunlight hours per day, monthly generation estimates, current usage of electricity and estimated percentage generation for net metering.

5. A method as in claim 1, wherein said consumer's customer variables are selected from the group consisting of local weather, current energy usage, desirable temperature, percentage used during sunlight hours, percentage used during peak hours, temperature zones and local utility policies on net metering, current utility costs during peak hours, current utility cost during off peak hours and client payment for system.

6. A method as in claim 1, wherein said at least one locally based renewable power system is selected from the group consisting of solar system, solar panel system, photovoltaic, thermal, wind powered, geothermal, hydropower.

7. A method as in claim 1, wherein said at least one locally based renewable power system's available incentives are selected from the group consisting of state, federal, local and equipment.

8. A method as in claim 1, further comprising the step of:
monitoring said system from a remote location.

9. A method as in claim 1, further comprising the step of:
Generating an alert when said customer variables are a prescribed percentage different than historical averages.

10. A method as in claim 1, further comprising the step of:
monitoring and storing said consumer's customer variables, said break even point and said aggregate cost.

11. A method as in claim 1, further comprising the step of:
remotely changing at least one of said consumer's customer variables according to said consumer's desired consumer monthly payment.

12. A method as in claim 1, further comprising at least one third party owner, wherein said third party owner owns said at least one locally based renewable power system and leases said at least one locally based renewable power system to said consumer.

13. A method as in claim 1, further comprising at least one third party owner, wherein said third party owner owns said at least one locally based renewable power system and leases said at least one locally based renewable power system to a third party financer.

14. A method as in claim 1, further comprising the step of:
selling energy from said at least one locally based renewable power system to a recipient;
receiving income from said recipient;
adjusting said customer variables including usage and
adjusting said consumers monthly payment.

15. A method of providing power as it is generated at a consumer's premises, said method comprising:
providing at least one locally based renewable power system to a consumer;
storing said at least one locally based renewable power system's characteristics in a database;
determining said consumer's customer variables including actual customer usage;
determining said at least one locally based renewable power system's available incentives;
determining the consumers monthly payment according to said consumer's actual customer usage and said available incentives; and
monitoring said consumer's customer usage on an ongoing basis to provide an actual customer usage;
billing said consumer said consumers monthly payment

16. A method as in claim 15, wherein said step of determining the consumers monthly payment is further according to said actual customer usage, said break even point and said aggregate cost.

17. A method as in claim 15, wherein said at least one locally based renewable power system's characteristics are selected from the group consisting of initial power system cost, component cost, installation costs, total wattage, average sunny days per year, average prime sunlight hours per day, monthly generation estimates, current usage of electricity and estimated percentage generation for net metering.

18. A method as in claim 15, wherein said consumer's customer variables are selected from the group consisting of local weather, current energy usage, desirable temperature, percentage used during sunlight hours, percentage used during peak hours, temperature zones and local utility policies on net metering, current utility costs during peak hours, current utility cost during off peak hours and client payment for system.

19. A method as in claim 15, wherein said at least one locally based renewable power system is selected from the group consisting of solar system, solar panel system, photovoltaic, thermal, wind powered, geothermal and hydropower.

20. A method as in claim 15, wherein said at least one locally based renewable power system's available incentives are selected from the group consisting of state, federal, local and equipment.

21. A method as in claim 15, further comprising the step of:
monitoring said system from a remote location.

22. A method as in claim 15, further comprising the step of:
generating an alert when said customer variables are a prescribed percentage different than historical averages.

23. A method as in claim 15, further comprising the step of:
monitoring and storing said consumer's customer variables, said break even point and said aggregate cost.

24. A method as in claim 15, further comprising the step of:
remotely changing at least one of said consumer's customer variables according to said consumer's desired consumer monthly payment.

25. A method as in claim 15, further comprising at least one third party owner, wherein said third party owner owns said at least one locally based renewable power system and leases said at least one locally based renewable power system to said consumer.

26. A method as in claim 15, further comprising the step of:
selling energy from said at least one locally based renewable power system to a recipient;
receiving income from said recipient; and
adjusting said consumers monthly payment.

27. A system for providing power at a consumer's premises and billing said consumer according to usage, said system comprising:
at least one locally based renewable power system at a consumer's location, wherein said at least one locally based renewable power system has power system characteristics and available incentives and said locally based renewable power system characteristics and said available incentives are stored in a database;
a set of customer variables, wherein said customer variables are maintained in a database;
a central processing unit in communication with said database, wherein said central processing unit determines a break even point of said at least one locally based renewable power system according to a discount rate, amortization period of said at least one locally based renewable power system and said database determines the consumers monthly payment according to said consumer's customer variables, said break even point and provides billing to said consumer according to said consumers monthly payment.

28. A system as in claim 27, wherein said at least one locally based renewable power system's characteristics are selected from the group consisting of initial power system cost, component cost, installation costs, total wattage, average sunny days per year, average prime sunlight hours per day, monthly generation estimates, current usage of electricity and estimated percentage generation for net metering.

29. A method as in claim 27, wherein said consumer's customer variables are selected from the group consisting of local weather, current energy usage, desirable temperature, percentage used during sunlight hours, percentage used during peak hours, temperature zones and local utility policies on net metering, current utility costs during peak hours, current utility cost during off peak hours and client payment for system.

30. A system as in claim 27, wherein said at least one locally based renewable power system is selected from the group consisting of solar system, solar panel system, photovoltaic, thermal, wind powered, geothermal and hydropower.

31. A system as in claim 27, wherein said at least one locally based renewable power system's available incentives are selected from the group consisting of state, federal, local and equipment.

32. A system as in claim 27, further comprising:
a communication means, wherein said communication means is in communication with said locally based renewable power system and said database and said central processing unit.

33. A system as in claim 27, further comprising:
a power system device controller, wherein said power system device controller is in communication with said communication means.

34. A system as in claim 27, further comprising at least one third party owner, wherein said third party owner owns said at least one locally based renewable power system and leases said at least one locally based renewable power system to said consumer.

35. A system as in claim 27, further comprising at least one recipient, wherein said consumer sells any excess energy from a locally based renewable power system to a recipient, said consumer receives income from said recipient; and said consumers monthly payment.

36. A system as in claim 27, further comprising the step of:
determining the aggregate cost of said at least one locally based renewable power system;
determining the consumers monthly payment according to said aggregate cost, said consumer's customer variables including actual usage, said break even point; and
providing billing to said consumer according to said consumers monthly payment.
